(19) United States
(12) Patent Application Publication
(10) Pub. No.: US 2012/0211059 A1
(43) Pub. Date: Aug. 23, 2012

(54) PENETRATED GROUND MOUNT SOLAR RACKING SYSTEM

(76) Inventor: Paul Anthony Tomaso, Jersey City, NJ (US)

(21) Appl. No.: 13/399,000

(22) Filed: Feb. 17, 2012

Related U.S. Application Data
(60) Provisional application No. 61/444,858, filed on Feb. 21, 2011.

(51) Int. Cl. H01L 31/048

(52) U.S. Cl. 136/251

(57) ABSTRACT

The present invention is a penetrated ground mount solar racking system with a top that includes a plurality of C-shaped channels that are disposed on top of the system, a plurality of U-shaped channels that are disposed on top of the system and are attached to the C-shaped channels forming a plurality of I-beam supports and a plurality of ground screws that are attached to the I-beam supports and are inserted into a penetrable surface. The system also includes a plurality of photovoltaic modules that are removably attached to the I-beam supports that receive sunlight and convert the sunlight into electrical energy, a plurality of adjustable support bracket that includes an I-beam support clamp, a fastener and a washer and are disposed on top of the ground screws and a photovoltaic module bracket that includes an I-beam solar slider, a slider clamp portion and a fastener.

This application claims priority to U.S. Provisional Application 61/444,858 filed on Feb. 21, 2011, the entire disclosure of which is incorporated by reference.

### TECHNICAL FIELD & BACKGROUND

The present invention generally relates to a solar racking system. More specifically, the invention is a penetrated ground mount solar racking system.

It is an object of the invention to provide a penetrated ground mount solar racking system that supports a plurality of photovoltaic modules that are installed on an uneven ground surface.

It is an object of the invention to provide a penetrated ground mount solar racking system that is intended to make a level installation of the system despite a varied terrain.

It is an object of the invention to provide a penetrated ground mount solar racking system that is relatively fast and easy to assemble with all fastening requirements being comfortably and easily performed on the top of the system.

What is really needed is a penetrated ground mount solar racking system that supports a plurality of photovoltaic modules that are installed on an uneven ground surface that is intended to make a level installation of the system despite a varied terrain that is relatively fast and easy to assemble with all fastening requirements being comfortably and easily performed on the top of the system.

### BRIEF DESCRIPTION OF THE DRAWINGS

The present invention will be described by way of exemplary embodiments, but not limitations, illustrated in the accompanying drawing in which like references denote similar elements and in which:

FIG. 1 illustrates a top perspective view of a penetrated ground mount solar racking system with a plurality of removed photovoltaic modules, in accordance with one embodiment of the present invention.

FIG. 2 illustrates a front perspective view of an adjustable support bracket utilized in combination with a penetrated ground mount solar racking system, in accordance with one embodiment of the present invention.

FIG. 3 illustrates a front perspective view of a photovoltaic module bracket utilized in combination with a penetrated ground mount solar racking system, in accordance with one embodiment of the present invention.

### DETAILED DESCRIPTION OF ILLUSTRATIVE EMBODIMENTS

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention. However, the order of description should not be construed as to imply that these operations are necessarily order dependent. In particular, these operations need not be performed in the order of presentation.

The phrase “in one embodiment” is used repeatedly. The phrase generally does not refer to the same embodiment, however, it may. The terms “comprising”, “having” and “including” are synonymous, unless the context dictates otherwise.

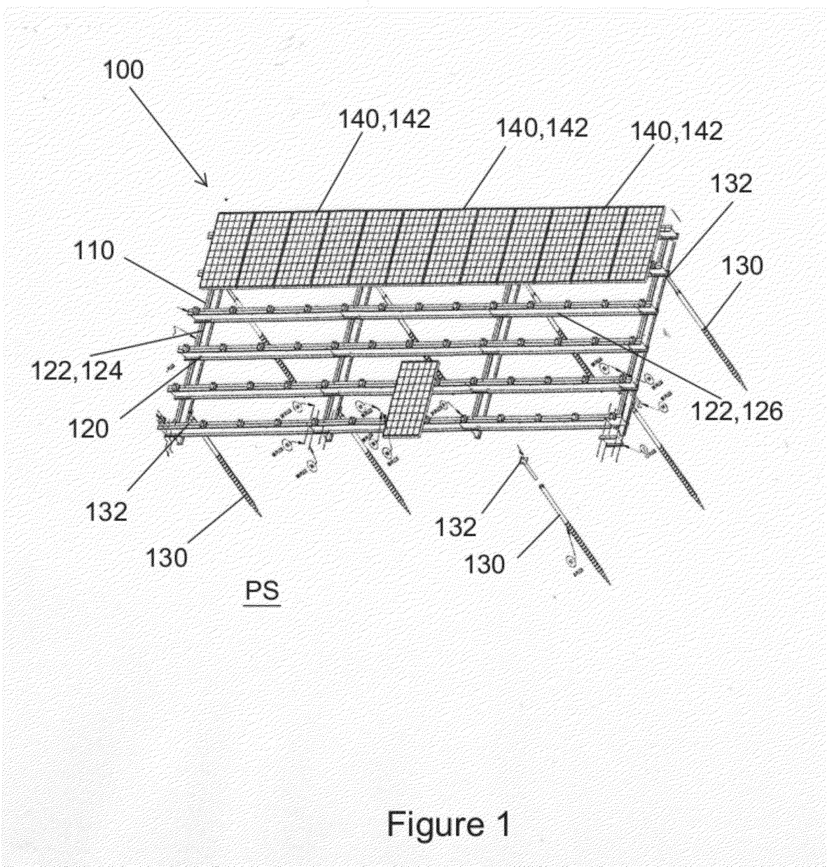

FIG. 1 illustrates a top perspective view of a penetrated ground mount solar racking system 100, in accordance with one embodiment of the present invention. The system 100 includes a plurality of C-shaped channels 110, a plurality of U-shaped channels 120, a plurality of ground screws 130 and a plurality of photovoltaic modules 140. The C-shaped channels 110 are disposed on top of the system 100 and are made of light gauge galvanized metal, but can be made of any other suitable material. The U-shaped channels 120 are also disposed on top of the system 100 and are attached to the C-shaped channels 110 forming a plurality of I-beam supports 122. The I-beam supports 122 include a plurality of main beams 124 and a plurality of support beams 126. The U-shaped channels 120 are also made of light gauge galvanized metal, but can be made of any other suitable material. The ground screws 130 have a top 132 and are attached to the support beams 126 and are inserted into a penetrable surface PS that is typically an uneven ground surface but can be any type of suitable penetrable surface. The photovoltaic modules 140 are removably attached to the I-beam supports 122 and are typically solar modules 142 that receive sunlight and convert the sunlight into energy which is typically electrical energy or other suitable energy.

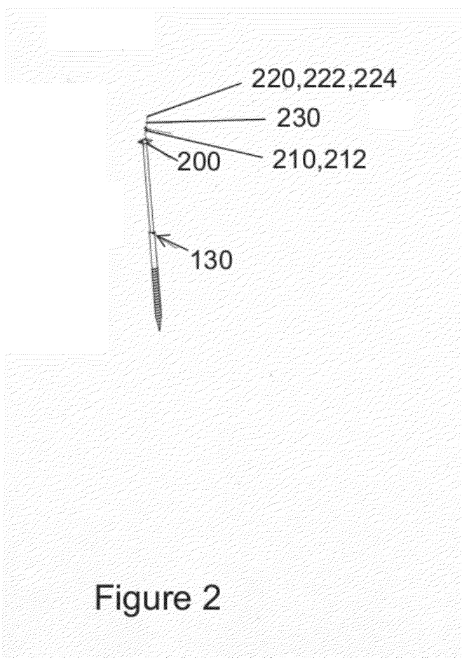

FIG. 2 illustrates a front perspective view of an adjustable support bracket 200 utilized in combination with a penetrated ground mount solar racking system, in accordance with one embodiment of the present invention. The penetrated ground mount solar racking system is a similar penetrated ground mount solar racking system 100 illustrated and described in FIG. 1 and its description. The adjustable support brackets 200 are disposed on the top 132 of the ground screws 130 and utilize a non-penetrating clamping technique to secure the adjustable support bracket 200 anywhere along the length of the I-beam supports 122 that are previously described and illustrated in FIG. 1 and its description.

The adjustable support bracket 200 includes a support clamp 210, a fastener 220 and a washer 230. The support clamp 210 is an I-beam support clamp 212 to accommodate the previously described I-beam supports 122. The fastener 220 can be any type of screw 222 or bolt 224 or other suitable fastener. The washer 230 accommodates the screw 222 or bolt 224 that is extended through the washer 230 and is additionally extended through the I-beam support clamp 212. The washer 230 can be any suitable washer 230 to accommodate the screw 222 or bolt 224 and I-beam support clamp 212.

The fastener is centered on the connection from the adjustable support bracket to the I-beam support. This allows for the adjustable support bracket to pivot in the event that the ground screw is not set vertically, but the adjustable support bracket will still remain level. This self-levels the adjustable support bracket across the entire system installation. The adjustable support bracket utilizes a non-penetrating clamping technique that allows it to be secured at any point along the length of the I-beam support. If there are site-specific obstructions (rocks, stumps, etc.) that prevent the ground screws from being installed in the planned location, the adjustable support bracket makes it possible to connect to the I-beam support at a different point along its length. The adjustable girder support bracket is fabricated with a press nut to eliminate field hardware required to fasten the adjustable support bracket to the I-beam supports. The bracket and clamp are designed such that has eliminated connection hardware by interfacing the parts with a nesting technique. Opposite the clamp, the bracket incorporates a 135-degree J-hook that secures the I-beam support bottom flange. This allows the bracket to resist both uplift and downforce as it mates to the I-beam supports. The bracket incorporates an automatic tilt angle for the array based on the bend techniques and hole locations.

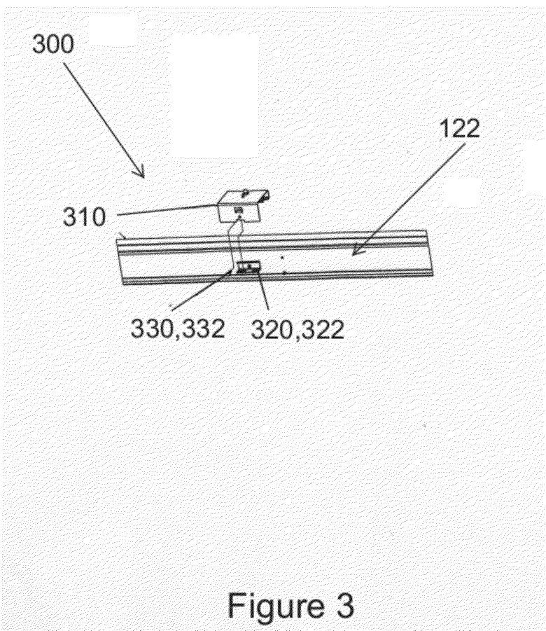

FIG. 3 illustrates a front perspective view of a photovoltaic module bracket 300 utilized in combination with a penetrated ground mount solar racking system, in accordance with one embodiment of the present invention. The penetrated ground mount solar racking system is a similar penetrated ground mount solar racking system 100 illustrated and described in FIG. 1 and its description. The photovoltaic module brackets 300 are secured anywhere along the length of the I-beam supports 122 that are previously described and illustrated in FIG. 1 and its description.

The photovoltaic module bracket 300 includes an I-beam solar slider 310, a slider clamp portion 320 and a fastener 330. The I-beam solar slider 310 securely slides an attached photovoltaic module (FIG. 1, 140) along an I-beam support 122. The slider clamp portion 320 includes a press nut 322 to eliminate field hardware required to fasten the photovoltaic module bracket 300 to the I-beam support 122. The photovoltaic module bracket 300 is fabricated with a press nut 322 to create a top down assembly approach that does not require hardware as photovoltaic modules 140 are being installed. The fastener 330 is a screw 332 but can be any suitable fastener to secure the photovoltaic module brackets 300 anywhere along the length of the I-beam supports 122.

The photovoltaic module bracket utilizes a non-penetrating clamping technique that allows the universal module bracket to be secured at any point along the length of the I-beam supports. The adjustability allows for all photovoltaic module types to be supported at multiple standard test conditions (STC) locations required for installation. The photovoltaic module bracket reduces the material required and structural cost for the I-beam supports by distributing the point load reactions from the photovoltaic modules. The slider clamp portion is fabricated with a press nut to eliminate field hardware required to fasten the photovoltaic module bracket to the purlin. The photovoltaic module bracket is fabricated with a press nut to create a top down assembly approach that does not require hardware as photovoltaic modules are being installed. The photovoltaic module bracket includes a ½″ tab centered on the piece to allow for the automatic spacing of the photovoltaic modules and reduces the time of installation. The photovoltaic module bracket and slider clamp portion are designed as such that connection hardware has been eliminated by interfacing the system components with a nesting technique. Opposite of the slider clamp portion, the photovoltaic module bracket incorporates a 90-degree bend and a 135-degree J-hook to allow the structural design to resist both uplift and downforce as the photovoltaic module bracket mates to the I-beam support purlin.

The penetrated ground mount solar racking system was developed in order to support photovoltaic modules that are installed on uneven ground. This racking system is intended to make installations level despite varied terrain. Light gauge galvanized sheet metal is formed into C-channels and U-channels making the system light weight and strong. Assembly of the components is relatively fast and easy with all fastening requirements being performed on the top of the system without having an installer to position themselves awkwardly. The racking is adjustable to allow for variance in uneven ground to help maintain a uniformed tilt angle. The ground screws are first installed with a tolerance of approximately one inch. The C-channels have slots to allow for the approximate one inch tolerance. After the ground screws are placed, the leg supports are held in place by set-screws, which are part of the ground screw. The leg support has a flange on one side, and a mounting bracket which slides over the flange on the opposite side. The mounting bracket has a screw hole in the center, which causes a pivoting motion to hold the support beam in place. The mounting bracket will allow for fine tuning of the ground screw location. The penetrated ground mount racking system can be used on various ground coverage. The racking system supports mono crystalline solar modules at a variable tilt to optimize solar production in a defined space. The racking structure is comprised of multiple C-channels and U-channels attached to form I-beams. There are two primary 1-beams, the main beam and the support beam. There are six main beams which are attached perpendicular to the top of the support beam. The support beam is attached to the ground screw with an adjustable bracket, which is attached to the ground screw. The solar modules are then attached to the main beam with a light gauge metal bracket and end clamps.

While the present invention has been related in terms of the foregoing embodiments, those skilled in the art will recognize that the invention is not limited to the embodiments described. The present invention can be practiced with modification and alteration within the spirit and scope of the appended claims. Thus, the description is to be regarded as illustrative instead of restrictive on the present invention.

1. A penetrated ground mount solar racking system with a top, comprising:
a plurality of C-shaped channels that are disposed on said top of said system;
a plurality of U-shaped channels that are disposed on said top of said system and are attached to said C-shaped channels forming a plurality of I-beam supports;
a plurality of ground screws that have a top and are attached to said I-beam supports and are inserted into a penetrable surface;
a plurality of photovoltaic modules that are removably attached to said I-beam supports that receive sunlight and convert the sunlight into electrical energy;
a plurality of adjustable support bracket that includes an I-beam support clamp, a fastener and a washer and are disposed on said top of said ground screws; and
a photovoltaic module bracket that includes an I-beam solar slider, a slider clamp portion and a fastener.

2. The system according to claim 1, wherein said C-shaped channels are made of light gauge galvanized metal.

3. The system according to claim 1, wherein said penetrable surface is an uneven ground surface.

4. The system according to claim 1, wherein said adjustable support brackets are secured anywhere along said I-beam supports to utilize a non-penetrating clamping technique.

5. The system according to claim 1, wherein said fasteners are a screw.

6. The system according to claim 1, wherein said washer accommodates said fastener that is extended through said washer with said fastener extended through said I-beam support clamp.

7. The system according to claim 1, wherein said I-beam solar slider securely slides said photovoltaic module along said I-beam support.

8. The system according to claim 1, wherein said slider clamp portion includes a press nut to fasten said photovoltaic module bracket to said I-beam support.

9. The system according to claim 8, wherein said photovoltaic module bracket is fabricated with said press nut to create a top down assembly approach to install said system.

10. The system according to claim 1, wherein said fastener is a screw to secure said photovoltaic module brackets anywhere along said I-beam supports.

11. A penetrated ground mount solar racking system with a top, comprising:
a plurality of C-shaped channels that are made of light gauge galvanized metal that are disposed on said top of said system;
a plurality of U-shaped channels made of light gauge galvanized metal that are disposed on said top of said system and are attached to said C-shaped channels forming a plurality of I-beam supports;
a plurality of ground screws that have a top and are attached to said I-beam supports and are inserted into a penetrable surface;
a plurality of photovoltaic modules that are removably attached to said I-beam supports that receive sunlight and convert the sunlight into electrical energy;
a plurality of adjustable support bracket that includes an I-beam support clamp, a fastener and a washer and are disposed on said top of said ground screws; and
a photovoltaic module bracket that includes an I-beam solar slider, a slider clamp portion and a fastener.

12. The system according to claim 11, wherein said penetrable surface is an uneven ground surface.

13. The system according to claim 11, wherein said adjustable support brackets are secured anywhere along said I-beam supports to utilize a non-penetrating clamping technique.

14. The system according to claim 11, wherein said fasteners are a screw.

15. The system according to claim 11, wherein said fasteners are a bolt.

16. The system according to claim 11, wherein said washer accommodates said fastener that is extended through said washer with said fastener extended through said I-beam support clamp.

17. The system according to claim 11, wherein said I-beam solar slider securely slides said photovoltaic module along said I-beam support.

18. The system according to claim 11, wherein said slider clamp portion includes a press nut to fasten said photovoltaic module bracket to said I-beam support.

19. The system according to claim 18, wherein said photovoltaic module bracket is fabricated with said press nut to create a top down assembly approach to install said system.

20. The system according to claim 11, wherein said fastener is a screw to secure said photovoltaic module brackets anywhere along said I-beam supports.
